(19) United States
(12) Patent Application Publication
(10) Pub. No.: US 2009/0250714 A1
(43) Pub. Date: Oct. 8, 2009

(54) White light emitting diode and lighting apparatus using the same

(75) Inventors: Mi Jeong Yun, Daejeon (KR); Kyeong Ik Min, Seoul (KR)

Correspondence Address: MCDERMOTT WILL & EMERY LLP, 600 13TH STREET, N.W., WASHINGTON, DC, 20005-3096, US

(73) Assignee: SAMSUNG ELECTRO-MECHANICS CO., LTD.

(21) Appl. No.: 12/155,276

(22) Filed: Jun. 2, 2008

(30) Foreign Application Priority Data
Apr. 3, 2008 (KR) 10-2008-0031147

(51) Int. Cl. H01L 33/00

(52) U.S. Cl. 257/98; 257/E33.055

(57) ABSTRACT

Provided is a white LED including a substrate having a reflecting body provided thereon; an LED chip mounted on the substrate; a fluorescence reflecting layer formed on the LED chip; and a phosphor layer formed on the fluorescence reflecting layer and having a higher refractive index than the fluorescence reflecting layer.

### CROSS-REFERENCE TO RELATED APPLICATIONS

This application claims the benefit of Korean Patent Application No. 10-2008-0031147 filed with the Korea Intellectual Property Office on Apr. 4, 2008, the disclosure of which is incorporated herein by reference.

### BACKGROUND OF THE INVENTION

1. Field of the Invention

The present invention relates to a white light emitting diode (LED) and a lighting apparatus using the same.

2. Description of the Related Art

An LED is referred to as a device which generates minority carriers (electrons or holes) injected by using the p-n junction structure of semiconductor and emits light by recombining the minority carriers. As for the LED, a red LED using GaAsP or the like, a green LED using GaP or the like, and a blue LED using InGaN/AlGaN double hetero structure are provided.

The LED has low power consumption and a long lifespan. Further, the LED can be installed in a narrow space, and has high resistance to vibration. The LED is used as a display device and a backlight unit. Recently, researches are being actively conducted to apply the LED as a general lighting.

Recently, white LEDs as well as red, blue, or green LEDs are launched on the market. Since the white LEDs can be applied to various fields, it is expected that demand for the white LEDs is rapidly increasing.

The technique for implementing white light in the LED can be roughly divided into two techniques.

In the first technique, red, green, and blue LED chips are installed adjacent to each other, and lights emitted from the respective LED chips are mixed to implement white light. However, since the respective LED chips have different thermal or time characteristics, the color tones of the LED chips are changed depending on the surrounding environment. In particular, color spots may occur, which makes it difficult to implement a uniform mixed color.

In the second technique, phosphor is disposed in an LED chip. Some of primarily-emitted light from the LED chip and secondarily-emitted light, of which the wavelength is converted by the phosphor, are mixed to implement white light. For example, on an LED chip which emits blue light, phosphor materials are distributed, the phosphor materials emitting yellow-green or yellow light by using the blue light as an excitation source. Then, white light can be obtained by the blue light emitted from the LED chip and the yellow-green or yellow light emitted from the phosphor.

Between them, the second technique is generally used. In particular, the technique for implementing white light by using the blue LED chip and the yellow-green or yellow phosphor is most frequently used.

However, when the white light is implemented by the above-described techniques, some of fluorescence emitted by the phosphor excited by the light emitted from the LED chip collides with the surface of the LED chip so as to be reabsorbed, because a phosphor layer is applied on the LED chip. Therefore, luminance efficiency decreases, and a large amount of heat is generated from the LED chip.

### SUMMARY OF THE INVENTION

An advantage of the present invention is that it provides a white LED in which a fluorescence reflecting layer having a lower refractive index than a phosphor layer is provided between an LED chip and the phosphor layer so as to totally reflect some of fluorescence emitted from the phosphor layer in the upward direction, thereby minimizing the re-absorption of the fluorescence into the LED chip. Therefore, it is possible to enhance luminance efficiency and heat radiation characteristics.

Another advantage of the invention is that it provides a white LED lighting apparatus using the white LED.

Additional aspects and advantages of the present general inventive concept will be set forth in part in the description which follows and, in part, will be obvious from the description, or may be learned by practice of the general inventive concept.

According to an aspect of the invention, a white LED comprises a substrate having a reflecting body provided thereon; an LED chip mounted on the substrate; a fluorescence reflecting layer formed on the LED chip; and a phosphor layer formed on the fluorescence reflecting layer and having a higher refractive index than the fluorescence reflecting layer.

The LED chip may include at least one or more LEDs which generate blue, red, green, and ultraviolet (UV) wavelengths. Preferably, the LED chip includes a blue LED

The phosphor layer may be formed of phosphor which converts a wavelength into any one of yellow, red, and green wavelengths. Preferably, the phosphor layer is formed of yellow light emitting phosphor.

The phosphor layer may be formed by mixing resin with phosphor. The resin includes any one of epoxy, silicon, strained silicon, urethane resin, oxetane resin, acryl, polycarbonate, and polyimide.

The white LED may further comprise a transparent lens which is provided between the LED chip and the fluorescence reflecting layer so as to surround the LED chip. The transparent lens may include any one of epoxy, silicon, strained silicon, urethane resin, oxetane resin, acryl, polycarbonate, and polyimide.

The transparent lens may be formed in a hemispherical shape. The fluorescence reflecting layer completely covers the transparent lens.

The fluorescence reflecting layer may be formed in a hemispherical shape. The fluorescence reflecting layer may be formed of an air layer.

According to another aspect of the invention, a white LED lighting apparatus comprises a substrate having a reflecting body provided thereon; an LED chip mounted on the substrate; a transparent lens covering the LED chip; a fluorescence reflecting layer formed on the transparent lens; a phosphor layer formed on the fluorescence reflecting layer and having a higher refractive index than the fluorescence reflecting layer; and a concentration lens formed on the phosphor layer.

The LED chip may include at least one or more LEDs which generate blue, red, green, and UV wavelengths. Preferably, the LED chip includes a blue LED.

The phosphor layer may be formed of phosphor which converts a wavelength into any one of yellow, red, and green wavelength. Preferably, the phosphor layer is formed of yellow light emitting phosphor.

The phosphor layer may be formed by mixing resin with phosphor. The resin includes any one of epoxy, silicon, strained silicon, urethane resin, oxetane resin, acryl, polycarbonate, and polyimide.

Preferably, the fluorescence reflecting layer completely covers the transparent lens. The fluorescence reflecting layer may be formed in a hemispherical shape.

The fluorescence reflecting layer may be formed of an air layer.

The concentration lens may be a compound parabolic concentrator or a parabola-shaped reflector.

The concentration lens may be coated with a reflective material.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a schematic cross-sectional view of a white LED lighting apparatus using a white LED according to the invention; and

FIG. 2 is a diagram showing optical paths of the white LED lighting apparatus according to the invention.

### DETAILED DESCRIPTION OF THE PREFERRED EMBODIMENTS

Reference will now be made in detail to the embodiments of the present general inventive concept, examples of which are illustrated in the accompanying drawings, wherein like reference numerals refer to like elements throughout. The embodiments are described below in order to explain the present general inventive concept by referring to the figures.

Hereinafter, a white LED and a white LED lighting apparatus using the same according to the present invention will be described in detail with reference to the accompanying drawings.

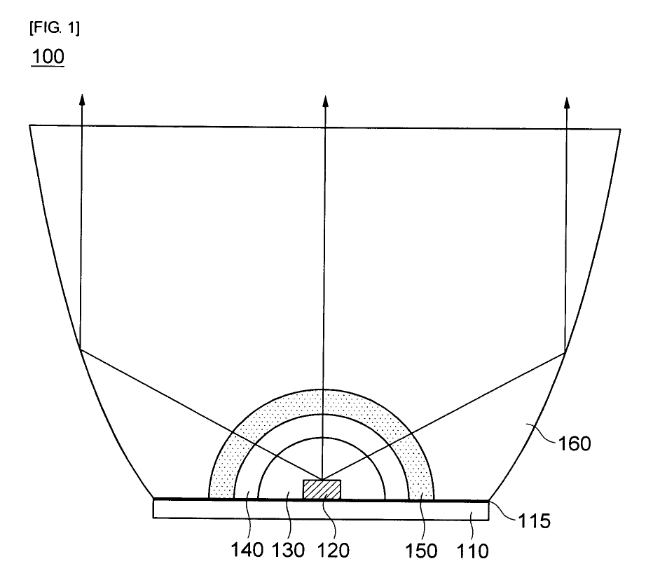

FIG. 1 is a schematic cross-sectional view of a white LED lighting apparatus using a white LED according to the invention.

As shown in FIG. 1, the white LED lighting apparatus 100 according to the invention includes a substrate 110, an LED chip 120 mounted on the substrate 110, a fluorescence reflecting layer 140 formed on the LED chip 120, and a phosphor layer 150 formed on the fluorescence reflecting layer 140.

A reflecting body 115 is provided on the substrate 110. The reflecting body 115 totally reflects light, which is emitted from the LED chip 120 so as to be incident on the bottom surface, in the upward direction, thereby enhancing luminance efficiency.

Further, the reflecting body 115 reflects light, which is emitted from the phosphor layer 150 so as to be directed to the LED chip 120, in the upward direction. That is, the reflecting body 115 reflects light directed to the opposite direction to the light irradiation direction in the upward direction, thereby further enhancing light extraction efficiency.

The LED chip 120 may include one or more LEDs which generate blue, red, green and ultraviolet (UV) wavelengths. For example, the LED chip 120 may include only a blue LED or both blue and red LEDs.

However, the present invention is not limited to such examples. If blue, red, green and ultraviolet (UV) wavelengths can be generated, an LED can be independently used or another combination of LEDs can be used.

The phosphor layer 150 is formed by mixing glass or transparent resin with phosphor materials. A material of the transparent resin is not limited specifically, as long as it can transmit light generated from the LED chip 110 and light emitted from the phosphor materials and can stably disperse the phosphor materials.

For example, the transparent resin may be formed of any one of polymethyl methacrylate (PMMA), polysterene, polyurethane, benzoguanamine resin, epoxy, and silicon resin.

The phosphor materials may be formed of phosphor which converts a wavelength into any one of yellow, red, and green wavelengths. The phosphor materials of the phosphor layer 150 are determined depending on the light emission wavelength of the LED chip 120. That is, such phosphor materials are used, that can convert light emitted from the LED chip 120 so as to implement white light.

For example, when the LED chip 120 generates blue light, the phosphor layer 150 is formed of phosphor which can emit yellow light.

As such, when the blue LED and the yellow light emitting phosphor are used, blue light emitted from the LED chip 120 and yellow light emitted from the phosphor materials using some of the blue light as an excitation source are combined during the application of current, thereby implementing white light.

The LED chip 120 is surrounded by a transparent lens 130. The transparent lens 130 completely covers the LED chip 120 so as to protect the LED chip 120. Further, the transparent lens 130 formed in a hemispherical shape reduces Fresnel reflection at the interface, thereby increasing light extraction efficiency. The transparent lens 130 is formed of resin which includes any one of epoxy, silicon, strained silicon, urethane resin, oxetane resin, acryl, polycarbonate, and polyimide.

The fluorescence reflecting layer 140 is formed on the transparent lens 130 so as to completely cover the transparent lens 130 and has a lower refractive index than the phosphor layer 150.

That is, the fluorescence reflecting layer 140 is formed in a hemispheric shape, similar to the transparent lens 130. The fluorescence reflecting layer 140 is formed of a material having a lower refractive index than the phosphor layer 150, for example, an air layer. However, the fluorescence reflecting layer 140 is not limited to the air layer. As described above, any other material can be used, as long as the material has a lower refractive index than the phosphor layer 150 and transmits light.

Since the fluorescence reflecting layer 140 has a lower refractive index than the phosphor layer 150, the fluorescence reflecting layer 140 totally reflects light which is emitted from the phosphor layer 150 so as to be incident at more than a critical angle such that some of the light incident toward the LED chip 120 is bent upward.

That is, light which is emitted from the LED chip 120 so as to be transmitted through the transparent lens 130 and the fluorescence reflecting layer 140 excites the phosphor materials while passing through the phosphor layer 150. Then, fluorescence is emitted by the exited phosphor materials, and some of the fluorescence is directed to the LED chip 120, that is, in the opposite direction to the light irradiation direction. The fluorescence directed to the LED chip 120 is totally reflected in the upward direction (light irradiation direction) by the fluorescence reflecting layer 140.

This is based on the Fresnel law in which when light is incident from a medium having a relatively high refractive index toward a medium having a relatively low refractive index and the incident angle of the light incident toward the medium having a relatively low refractive index is more than a critical angle, total reflection occurs.

Therefore, the light which is totally reflected by the fluorescence reflecting layer 140 corresponds to light which is incident from the phosphor layer 150 toward the fluorescence reflecting layer 140 and of which the incident angle is more than a critical angle.

For example, when the phosphor layer 150 is formed of glass and the fluorescence reflecting layer 140 is formed of an air layer, light which is emitted from the phosphor layer 150 toward the fluorescence reflecting layer 140 and of which the incident angle is more than 42 degrees is totally reflected.

Therefore, the fluorescence reflecting layer 140 totally reflects some of light emitted from the phosphor materials toward the LED chip 120 (light which is emitted in the opposite direction to the light irradiation direction) in the upward direction (the light irradiation direction), thereby enhancing light extraction efficiency.

Further, the fluorescence reflecting layer 140 totally reflects some of light emitted from the phosphor layer 150 toward the LED chip 120 so as to reduce an amount of light reabsorbed into the LED chip 120, thereby further enhancing a heat radiation characteristic of the LED chip.

Since the light generated from the LED chip 120 is diffused by the phosphor materials of the phosphor layer 150, it is possible to reduce glare.

As such, since the fluorescence reflecting layer 140 having a lower refractive index than the phosphor layer 150 is provided between the transparent lens 130 and the phosphor layer 150 which surround the LED chip 120, some of light emitted from the phosphor layer 150 toward the LED chip 120 is totally reflected to thereby enhance luminance efficiency. In the invention, a concentration lens 160 may be further provided on the phosphor layer 150 so as to be applied to the lighting apparatus.

The concentration lens 160 may be a compound parabolic concentrator or a parabola-shaped reflector and serves to collect light, which is emitted in four directions through the phosphor layer 150, into a specific range, thereby enhancing luminance efficiency.

That is, when the concentration lens 160 is applied to a lighting apparatus, the concentration lens 160 prevents light from spreading in four directions and adjusts a lighting angle. In this case, the lighting angle is determined depending on the slope of a parabolic surface.

Further, the concentration lens 160 may be coated with reflective materials so as to adjust distribution of luminous intensity.

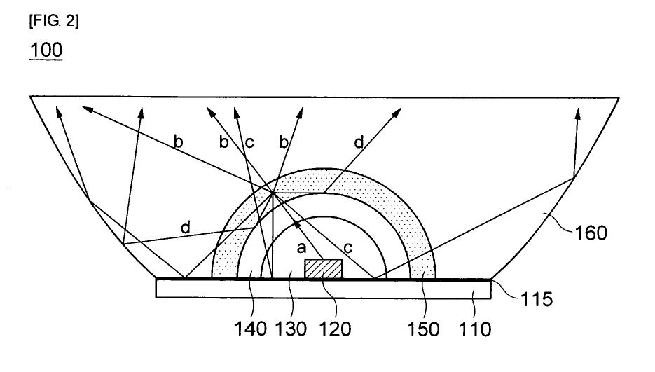

As shown in FIG. 2, when light (a) is emitted from the LED chip 120 of the LED lighting apparatus 100 according to the invention, the light (a) collides with the phosphor materials of the phosphor layer 150 so as to excite the phosphor materials distributed in the phosphor layer 150 and is then discharged upward (b) or directed downward (c). At this time, most of the light is discharged upward after exciting the phosphor materials, and the light directed downward is reflected by the reflecting body 115 formed on the substrate 110 so as to excite the phosphor materials 115 and is then discharged upward.

Meanwhile, the fluorescence which is generated from the phosphor materials excited by the light (a) emitted from the LED chip 120 so as to be directed upward is discharged in the light irradiation direction together with the light (a) emitted from the LED chip 120, thereby implementing white light. Further, the fluorescence which is emitted toward the LED chip 120 is totally reflected by the fluorescence reflecting layer 140 so as to be directed upward. At this time, the fluorescence (d) which is totally reflected by the fluorescence reflecting layer 140 is incident at more than a critical angle, and light (c) which is not totally reflected by the fluorescence reflecting layer 140 but is transmitted is reabsorbed by the LED chip 120 or is totally reflected by the reflecting body 115 of the substrate 110 so as to be discharged upward.

The light transmitted through the phosphor layer 150 passes through the concentration lens 160, and light reaching the interface of the concentration lens 160 is discharged upward (in the light irradiation direction), thereby implementing white light.

Therefore, the reflecting body 115 formed on the substrate, the fluorescence reflecting layer 140, the phosphor layer 150, and the concentration lens 160 contribute to enhancing the light extraction efficiency.

As described above, the fluorescence reflecting layer is provided between the transparent lens and the phosphor layer which surround the LED chip such that some of light which is emitted from the phosphor layer so as to be reabsorbed into the LED chip is discharged upward, thereby enhancing luminance efficiency and heat radiation characteristics. If a white LED and a lighting apparatus using the same include a fluorescence reflecting layer which is formed of a material having a lower refractive index than the phosphor layer and is provided between the LED chip and the phosphor layer regardless of the type of a substrate and the shape of a concentration lens, the white LED and the lighting apparatus may be included in the present invention.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

What is claimed is:

1. A white light emitting diode (LED) comprising:
a substrate having a reflecting body provided thereon;
an LED chip mounted on the substrate;
a fluorescence reflecting layer formed on the LED chip; and
a phosphor layer formed on the fluorescence reflecting layer and having a higher refractive index than the fluorescence reflecting layer.

2. The white LED according to claim 1, wherein the LED chip includes at least one or more LEDs which generate blue, red, green, and ultraviolet (UV) wavelengths.

3. The white LED according to claim 2, wherein the LED chip includes a blue LED.

4. The white LED according to claim 1, wherein the phosphor layer is formed of phosphor which converts a wavelength into any one of yellow, red, and green wavelengths.

5. The white LED according to claim 4, wherein the phosphor layer is formed of yellow light emitting phosphor.

6. The white LED according to claim 1, wherein the phosphor layer is formed by mixing resin with phosphor.

7. The white LED according to claim 6, wherein the resin includes any one of epoxy, silicon, strained silicon, urethane resin, oxetane resin, acryl, polycarbonate, and polyimide.

8. The white LED according to claim 1, wherein the phosphor layer is formed by mixing glass with phosphor.

9. The white LED according to claim 1 further comprising:
a transparent lens which is provided between the LED chip and the fluorescence reflecting layer so as to surround the LED chip.

10. The white LED according to claim 9, wherein the transparent lens includes any one of epoxy, silicon, strained silicon, urethane resin, oxetane resin, acryl, polycarbonate, and polyimide.

11. The white LED according to claim 9, wherein the transparent lens is formed in a hemispherical shape.

12. The white LED according to claim 9, wherein the fluorescence reflecting layer completely covers the transparent lens.

13. The white LED according to claim 12, wherein the fluorescence reflecting layer is formed in a hemispherical shape.

14. The white LED according to claim 1, wherein the fluorescence reflecting layer is formed of an air layer.

15. A white LED lighting apparatus comprising:
a substrate having a reflecting body provided thereon;
an LED chip mounted on the substrate;
a transparent lens covering the LED chip;
a fluorescence reflecting layer formed on the transparent lens;
a phosphor layer formed on the fluorescence reflecting layer and having a higher refractive index than the fluorescence reflecting layer; and
a concentration lens formed on the phosphor layer.

16. The white LED lighting apparatus according to claim 15, wherein the LED chip includes at least one or more LEDs which generate blue, red, green, and ultraviolet (UV) wavelengths.

17. The white LED lighting apparatus according to claim 15, wherein the LED chip includes a blue LED.

18. The white LED lighting apparatus according to claim 15, wherein the phosphor layer is formed of phosphor which converts a wavelength into any one of yellow, red, and green wavelength.

19. The white LED lighting apparatus according to claim 15, wherein the phosphor layer is formed of yellow light emitting phosphor.

20. The white LED lighting apparatus according to claim 15, wherein the fluorescence reflecting layer completely covers the transparent lens.

21. The white LED lighting apparatus according to claim 20, wherein the fluorescence reflecting layer is formed in a hemispherical shape.

22. The white LED lighting apparatus according to claim 15, wherein the fluorescence reflecting layer is formed of an air layer.

23. The white LED lighting apparatus according to claim 15, wherein the concentration lens is a compound parabolic concentrator.

24. The white LED lighting apparatus according to claim 15, wherein the concentration lens is a parabola-shaped reflector.

25. The white LED lighting apparatus according to claim 15, wherein the concentration lens is coated with a reflective material.
